(19) United States
(12) Patent Application Publication
(10) Pub. No.: US 2025/0022676 A1
(43) Pub. Date: Jan. 16, 2025

(54) ELECTRON BEAM DEVICE INCLUDING SCHOTTKY EMITTER AND METHOD OF OPERATING SCHOTTKY EMITTER

(71) Applicant: Hitachi High-Tech Corporation, Tokyo (JP)

(72) Inventors: Toshiaki KUSUNOKI, Tokyo (JP); Masahiro FUKUTA, Tokyo (JP); Yusuke SAKAI, Tokyo (JP); Soichiro MATSUNAGA, Tokyo (JP); Tomoya IGARI, Tokyo (JP)

(21) Appl. No.: 18/669,862

(22) Filed: May 21, 2024

(30) Foreign Application Priority Data
Jul. 14, 2023 (JP) 2023-115863

(51) Int. Cl. H01J 37/073

(52) U.S. Cl. CPC H01J 37/073; H01J 2237/06316

(57) ABSTRACT

An electron beam device includes a Schottky emitter that is capable of reproducing collapse of a shape of a facet in a short time without adding hardware. Also, a method of operating a Schottky emitter includes applying a first electric field to the Schottky emitter while heating the Schottky emitter at a first temperature, and then applying a second electric field to the Schottky emitter while heating the Schottky emitter at a second temperature. The first temperature is higher than an operation temperature of the Schottky emitter and the second temperature. The first electric field is equal to or higher than an operation electric field of the Schottky emitter and lower than the second electric field. The second temperature is equal to or higher than the operation temperature and lower than the first temperature. The second electric field is higher than the operation electric field and the first electric field.

### CLAIM OF PRIORITY

The present application claims priority from Japanese Patent Application JP 2023-115863 filed on Jul. 14, 2023, the content of which is hereby incorporated by reference into this application.

### TECHNICAL FIELD

The present invention relates to an electron beam device including a Schottky emitter and a method of operating a Schottky emitter provided in an electron beam device.

### BACKGROUND ART

A Schottky emitter (SE) is widely used in an electron beam device such as an electron microscope as an emitter capable of achieving both high spatial resolution and high stability operation, and is also called a thermal field emitter (TFE) because the Schottky emitter operates under a high temperature and high electric field.

An example of the Schottky emitter is a Zr/O/W emitter in which zirconium oxide (ZrO₂) serving as a supply source of zirconium (Zr) atoms and oxygen (O) atoms is provided in a body portion of a needle-like tungsten (W) single crystal having a (100) crystal surface at a tip end. The (100) crystal surface is called a facet, the needle-like tungsten single crystal is called a tip, and the zirconium oxide is called a reservoir. By the heating of the tip and the application of the electric field, Zr atoms and O atoms are supplied from the reservoir to the facet, a work function of the facet decreases. Further, the electric field concentrates on the tip end of the heated tip, whereby electrons are emitted from the facet. After the Zr/O/W emitter is used at an initial stage of start-up or a relatively low current density for a long period of time, a shape of the facet may collapse and an emission current may become unstable.

PTL 1 discloses a method of stabilizing an emission current by sequentially performing a first step and a second step described below on a Zr/O/W emitter in which a shape of a facet collapses. That is, in the first step, the shape of the facet is reproduced by setting a temperature of a tip to 1750 K or higher and lower than 1900 K and applying an electric field of 1.5 GV/m or higher and lower than 3.0 GV/m to the tip. In addition, in the second step, the stable emission current is maintained by setting the temperature of the tip to 1600 K or higher and lower than 1750 K, and applying the electric field of 0.5 GV/m or higher and lower than 1.5 GV/m to the tip.

PTL 2 discloses that collapse of a shape of a facet is reproduced by applying, to an extraction electrode provided to face a thermal field emitter, a voltage having a reverse polarity to that of a normal operation forward voltage.

### CITATION LIST

### Patent Literature

PTL 1: JPH06-28142B
PTL 2: JP2013-191353A

### SUMMARY OF INVENTION

### Technical Problem

However, in PTL 1, the first step of reproducing the shape of the facet requires about 20 hours. In addition, in PTL 2, although the facet can be reproduced in a relatively short time of about 30 minutes, it is necessary to add hardware for applying the voltage having a reverse polarity to the extraction electrode, for example, a power supply having a reverse polarity or a high-voltage changeover switch, and the manufacturing cost of the electron beam device increases.

Therefore, an object of the invention is to provide an electron beam device including a Schottky emitter and a method of operating a Schottky emitter, which are capable of reproducing collapse of a shape of a facet in a short time without adding hardware.

### Solution to Problem

In order to achieve the above object, the invention is an electron beam device including a Schottky emitter. The electron beam device includes: a heating source configured to heat the Schottky emitter; a power supply configured to apply an electric field to the Schottky emitter; and a control unit configured to control the heating source and the power supply. The control unit is configured to execute a first stage of applying a first electric field to the Schottky emitter while heating the Schottky emitter at a first temperature, and a second stage of applying a second electric field to the Schottky emitter while heating the Schottky emitter at a second temperature. The first temperature is higher than an operation temperature of the Schottky emitter and the second temperature. The first electric field is equal to or higher than an operation electric field of the Schottky emitter and lower than the second electric field. The second temperature is equal to or higher than the operation temperature and lower than the first temperature. The second electric field is higher than the operation electric field and the first electric field.

In addition, the invention is a method of operating a Schottky emitter. The method includes: executing a first stage of applying a first electric field to the Schottky emitter while heating the Schottky emitter at a first temperature, and a second stage of applying a second electric field to the Schottky emitter while heating the Schottky emitter at a second temperature. The first temperature is higher than an operation temperature of the Schottky emitter and the second temperature. The first electric field is equal to or higher than an operation electric field of the Schottky emitter and lower than the second electric field. The second temperature is equal to or higher than the operation temperature and lower than the first temperature. The second electric field is higher than the operation electric field and the first electric field.

### Advantageous Effects of Invention

According to the invention, it is possible to provide an electron beam device including a Schottky emitter and a method of operating a Schottky emitter, which are capable of reproducing collapse of a shape of a facet in a short time without adding hardware.

### BRIEF DESCRIPTION OF DRAWINGS

FIG. 1 is a diagram showing a configuration example of a scanning electron microscope as an example of an electron beam device according to the invention.

FIG. 2 is a schematic diagram showing a configuration example of an emitter according to the invention.

FIG. 3 is an enlarged schematic diagram showing a tip end of a tip of a Schottky emitter.

FIG. 4 is an enlarged schematic diagram showing the tip end of the tip formed with a dark ring.

FIG. 5 is a factor-effect diagram of a temperature and an electric field for a time until the dark ring is eliminated.

FIG. 6 is a diagram showing a physical model of the tip end of the tip corresponding to the factor-effect diagram.

FIG. 7 is a diagram for comparing a method of operating the Schottky emitter according to the invention with an operation method in the related art.

FIG. 8 is a diagram showing an example of a relationship between a filament current ratio and a tip temperature.

FIG. 9 is a diagram showing an example of a relationship between an effective voltage ratio and the electric field.

FIG. 10 is a diagram showing another example of the method of operating the Schottky emitter.

FIG. 11 is a diagram showing temporal changes in an emission current, a probe current, and a field emission microscopic image of a field emission microscope.

FIG. 12 is a diagram showing temporal changes in an emission current and a probe current of a scanning electron microscope.

### DESCRIPTION OF EMBODIMENTS

Hereinafter, embodiments of an electron beam device including a Schottky emitter and a method of operating a Schottky emitter according to the invention will be described with reference to the drawings.

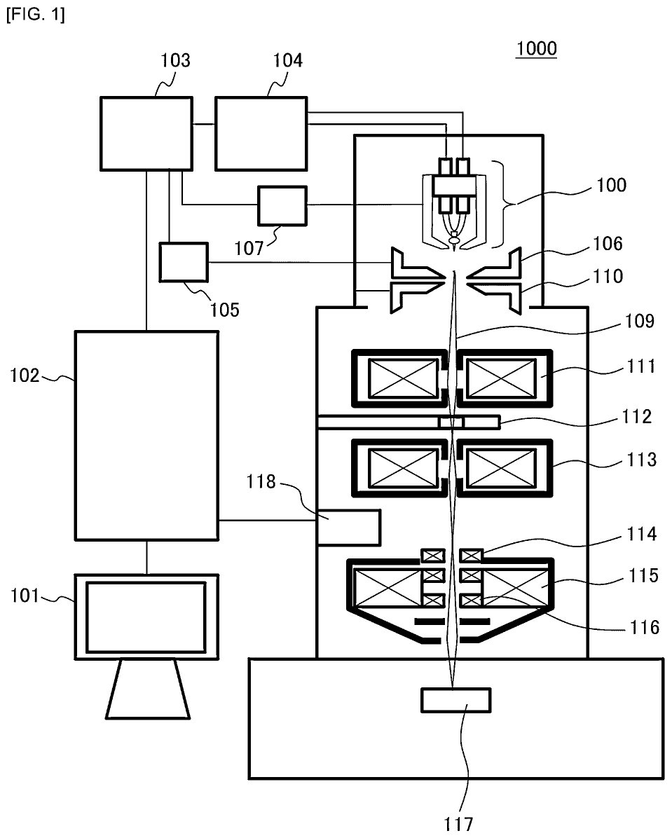

A configuration example of a scanning electron microscope (SEM) as an example of the electron beam device will be described with reference to FIG. 1. The electron beam device may be a field emission microscope, a transmission electron microscope (TEM), a scanning transmission electron microscope (STEM), or the like.

A scanning electron microscope 1000 includes a microscope body and a control system for irradiating a sample 117 with an electron beam 109. The microscope body includes an emitter 100, an extraction electrode 106, an anode 110, a first condenser lens 111, an aperture 112, a second condenser lens 113, an astigmatism correction coil 114, an objective lens 115, a deflection scanning coil 116, and a secondary electron detector 118, and the inside of the microscope boy is evacuated. The control system includes a computer 101, a controller 102, an acceleration power supply 103, a heating power supply 104, an extraction power supply 105, and a suppressor power supply 107.

The computer 101 controls the controller 102 based on an input from an operator. The controller 102 is, for example, an arithmetic unit such as a micro processing unit (MPU), controls the acceleration power supply 103, the heating power supply 104, the extraction power supply 105, and the suppressor power supply 107, and receives a detection signal from the secondary electron detector 118. The acceleration power supply 103 applies, to the emitter 100, a negative high voltage with respect to a ground voltage. The heating power supply 104 floated on the acceleration power supply 103 supplies a filament current to the emitter 100. The extraction power supply 105 applies, to the extraction electrode 106, a positive voltage with respect to the emitter 100. The suppressor power supply 107 applies a voltage to a suppressor electrode described later.

The emitter 100 emits the electron beam 109 by the heating due to the supply of the filament current and the application of the voltage to the extraction electrode 106. The electron beam 109 is accelerated by a voltage between the grounded anode 110 and the emitter 100. The accelerated electron beam 109 is focused by the first condenser lens 111, the aperture 112, the second condenser lens 113, the astigmatism correction coil 114, and the objective lens 115. The focused electron beam 109 performs scanning using the deflection scanning coil 116, and is irradiated onto an observation region on the sample 117. Secondary electrons generated from the sample 117 by the irradiation of the electron beam 109 are detected by the secondary electron detector 118. The detection signal of the secondary electron detector 118 is used to generate an observation image. In addition to the secondary electron detector 118, a reflected electron detector for detecting reflected electrons and an elemental analyzer for detecting fluorescent X-rays may be provided.

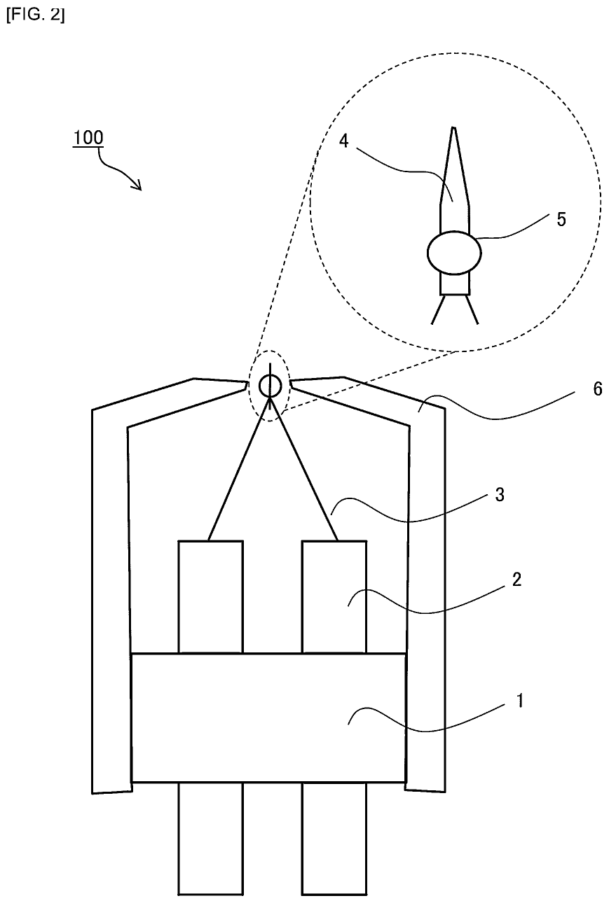

A configuration example of the emitter 100 will be described with reference to FIG. 2. In FIG. 2, the emitter 100 in FIG. 1 is turned upside down. The emitter 100 includes an insulator 1, electrode pins 2, a filament 3, a tip 4, a reservoir 5, and a suppressor electrode 6. The V-shaped filament 3 is welded to two electrode pins 2 passing through the ceramic insulator 1. The needle-like tip 4, which is sharp into a conical shape by electrolytic polishing or the like, is welded to a tip end of the filament 3. A body portion of the tip 4 is provided with the reservoir 5 for supplying atoms for decreasing a work function of the tip end of the tip 4. The tip 4 and the filament 3 are surrounded by the suppressor electrode 6 for preventing unnecessary thermal electron emission. A negative voltage with respect to the tip 4 and the filament 3 is applied to the suppressor electrode 6. In a Zr/O/W emitter, which is an example of

the Schottky emitter, a tungsten (W) single crystal having a orientation in a long axis direction is used for the tip 4, zirconium oxide (ZrO₂) is used for the reservoir 5, and zirconium (Zr) atoms and oxygen (O) atoms are supplied from the reservoir 5 to the tip 4.

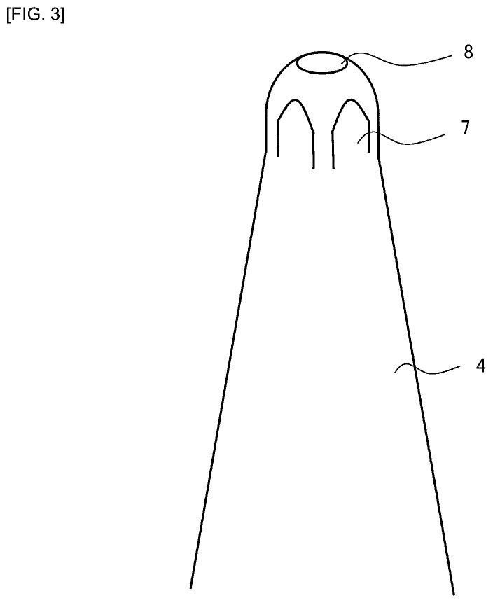

The tip end of the tip 4 of the Zr/O/W emitter will be described with reference to FIG. 3. When the tip 4 of the W single crystal is heated in vacuum and an electric field is applied to the tip 4, a columnar crystal structure 7 is formed by crystal growth, that is, so-called built-up, due to atomic flow to the tip end of the tip 4. In addition, a facet 8, which is a flat W (100) crystal surface, is formed at the most tip end of the columnar crystal structure 7 to serve as an electron emission surface. Further, by heating the tip 4, Zr atoms and O atoms, which are surface-diffused from the reservoir 5 to the facet 8, form a monomolecular film of Zr and O. Due to the formation of the monomolecular film, the work function of the facet 8, which is the electron emission surface, is lowered from 4.5 eV to 2.8 eV, and electrons are easily emitted.

In the Schottky emitter, the emission current may become unstable after the emitter is used at an initial stage of start-up or a relatively low current density for a long period of time. The unstable emission current is caused by the shape of the facet 8 being collapsed and a ring-shaped step structure called a dark ring being formed in the surface of the facet 8.

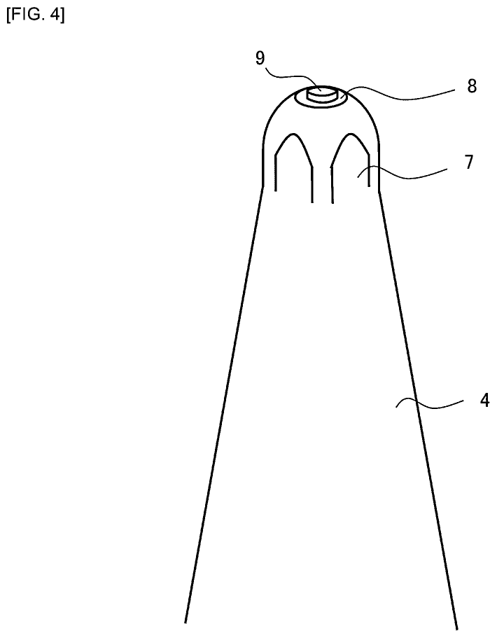

The dark ring formed in the facet 8 will be described with reference to FIG. 4. When the formation of the facet 8 is inappropriate at the initial stage of start-up of the Schottky emitter, or when a relatively low electric field is continuously applied to emit electrons at a relatively low current density and the building-up is weakened, a dark ring 9 is formed in the surface of the facet 8. In a step portion of the dark ring 9, the electric field is shielded or the surface diffusion of Zr atoms and O atoms is inhibited, so that electrons are less likely to be emitted as compared with the normal facet 8. In addition, the dark ring 9 moves in the surface of the facet 8 over time, and causes a probe current of the electron beam device to fluctuate. That is, in order to stably operate the electron beam device including the Schottky emitter, it is necessary to quickly eliminate the dark ring 9 and reproduce the facet 8.

Therefore, the inventors have analyzed a temperature of the tip 4 and an electric field applied to the tip 4 using an orthogonal table experiment under a condition that the dark ring 9 is quickly eliminated. In the orthogonal table experiment, three levels are respectively set for the temperature of the tip 4 of the Zr/O/W emitter and the electric field applied to the tip 4. Specifically, the three levels of the temperature are a high temperature region (1850 K or higher and lower than 2000 K), an intermediate temperature region (1700 K or higher and lower than 1850 K), and a low temperature region (1550 K or higher and lower than 1700 K) obtained by dividing a temperature range, in which the Zr/O/W emitter operates without being damaged, into three equal parts. In addition, the three levels of the electric field are a high electric field region (1.5 GV/m or higher and lower than 2.0 GV/m), an intermediate electric field region (1.0 GV/m or higher and lower than 1.5 GV/m), and a low electric field region (0.5 GV/m or higher and lower than 1.0 GV/m) obtained by dividing an electric field range, in which the Zr/O/W emitter operates without being damaged, into three equal parts. The temperature of the tip 4 is set by the filament current flowing through the filament 3. A correspondence relationship between the temperature of the tip 4 and the filament current may be acquired in advance. The electric field applied to the tip 4 is set by a voltage between the extraction electrode 106 and the suppressor electrode 6.

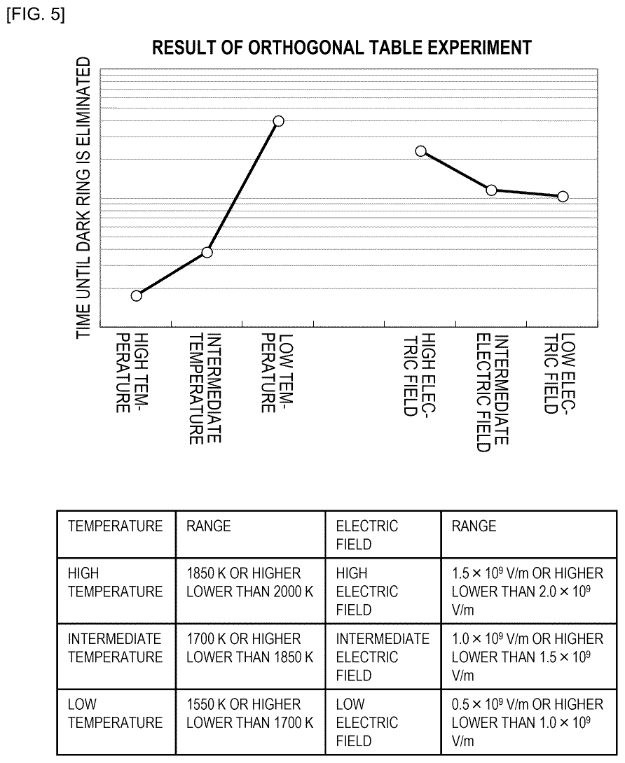

A factor-effect diagram as a result of the orthogonal table experiment will be described with reference to FIG. 5. A vertical axis in FIG. 5 represents the time until the dark ring 9 is eliminated, and a horizontal axis represents the temperature of the tip 4 or the electric field applied to the tip 4. The time until the dark ring 9 is eliminated is measured using an image obtained by the field emission microscope including a fluorescent surface on which the shape of the electron emission surface is enlarged and projected. When the three levels of the temperature are compared, the dark ring 9 is eliminated in the shortest time in the high temperature region, and the time until the dark ring 9 is eliminated in the order of the intermediate temperature region and the low temperature region becomes longer. On the other hand, when the three levels of the electric field are compared, the time until the dark ring 9 is eliminated in the high electric field region is longer than in the intermediate electric field region or the low electric field region. A slope of an elimination time for the temperature is larger than a slope of an elimination time for the electric field, and the slope from the low temperature region to the intermediate temperature region is particularly large.

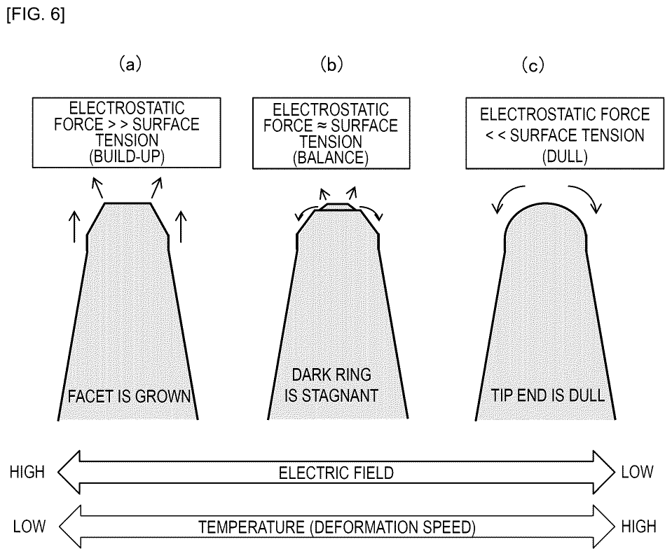

A physical model of the tip end of the tip corresponding to the factor-effect diagram will be described with reference to FIG. 6. W atoms in the tip end of the tip move in a direction of an arrow shown in FIG. 6 due to the influence of the temperature and the electric field. Specifically, when the temperature rises, the W atoms move toward the body portion of the tip such that the tip end of the tip is rounded due to a surface tension. In addition, under a high electric field, W atoms move toward the tip end such that static energy is stabilized. When a dark ring is generated, the tip end of the tip is in a state of (b), and the dark ring is not eliminated when the surface tension and an electrostatic force are balanced. Here, when the temperature of the tip is raised, the surface tension is larger than the electrostatic force, the tip end of the tip is dull to shift to a state of (c), and the dark ring is eliminated. Thereafter, when the temperature is lowered and the electric field is raised, the electrostatic force is larger than the surface tension, W atoms move toward the tip end, and the facet, which is a high density crystal surface, is grown to shift to a state of (a).

Under a high temperature and high electric field as in PTL 1, since the surface tension and the electrostatic force are balanced as in (b), the time until the dark ring is eliminated becomes long. In addition, in the state of (b), when the temperature is lowered and the electric field is raised, although the electrostatic force is larger than the surface tension, since the electric field is shielded by the step portion of the dark ring, movement of W atoms to the tip end is inhibited, and it takes a long time to eliminate the dark ring.

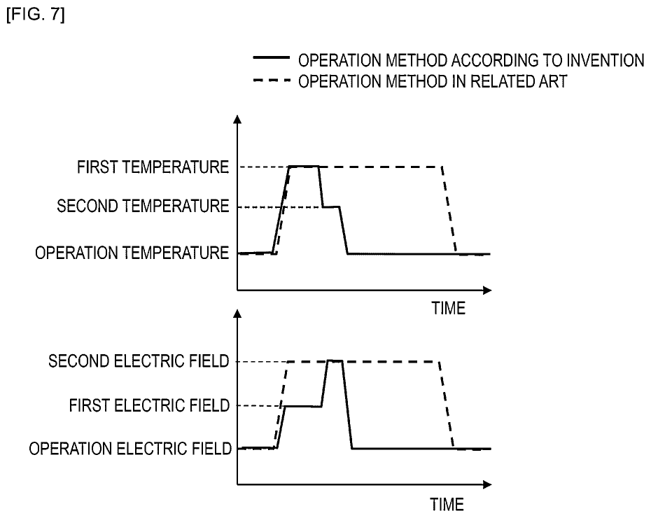

With reference to FIG. 7, an operation method according to the invention for the Schottky emitter in which the shape of the facet collapses is described in comparison with an operation method in the related art as in PTL 1. In FIG. 7, the upper part is a graph showing a temporal change in temperature, and the lower part is a graph showing a temporal change in electric field. In addition, the operation method according to the invention is indicated by a solid line, and the operation method in the related art is indicated by a dotted line.

In the operation method according to the invention, in a first stage, the temperature is changed from an operation temperature to a first temperature, the electric field is changed from an operation electric field to a first electric field, and the dark ring is eliminated. Thereafter, in a second stage, the temperature is changed from the first temperature to a second temperature, and the electric field is changed from the first electric field to a second electric field, and a facet is formed. The first temperature is higher than the operation temperature and the second temperature, and the second temperature is equal to or higher than the operation temperature and lower than the first temperature. In addition, the first electric field is equal to or higher than the operation electric field and lower than the second electric field, and the second electric field is higher than the operation electric field and the first electric field. The operation temperature is a temperature of the tip when a sample is observed by the electron beam device, and the operation electric field is an electric field applied to the tip when the sample is observed by the electron beam device.

As shown in the factor-effect diagram in FIG. 5, the time until the dark ring is eliminated is shorter as the temperature of the tip is higher, and the first temperature is preferably in the high temperature region (1850 K or higher and lower than 2000 K), but is effective in the intermediate temperature region (1700 K or higher and lower than 1850 K). The operation temperature of the Schottky emitter is in the low temperature region (1550 K or higher and lower than 1700 K) or in the intermediate temperature region (1700 K or higher and lower than 1850 K) depending on the purpose of use, so that it is important that the first temperature is higher than the operation temperature.

In addition, as shown in the factor-effect diagram in FIG. 5, the time until the dark ring is eliminated is shorter as the electric field applied to the tip is lower, and the first electric field is preferably from the low electric field region (0.5 GV/m or higher and lower than 1.0 GV/m) to the intermediate electric field region (1.0 GV/m or higher and lower than 1.5 GV/m). The operation electric field of the Schottky emitter is in the low electric field region (0.5 GV/m or higher and lower than 1.0 GV/m) or in the intermediate electric field region (1.0 GV/m or higher and lower than 1.5 GV/m) depending on the purpose of use, so that it is important that the first electric field is equal to or higher than the operation electric field and lower than the second electric field.

That is, in the first stage of the operation method according to the invention, the dark ring is eliminated by setting the temperature of the tip to the first temperature higher than the operation temperature, setting the electric field applied to the tip to the first electric field, which is equal to or higher than the operation electric field and lower than the second electric field, and maintaining the temperature and the first electric field for 10 minutes to several hours.

In the subsequent second stage, the second temperature is set lower than the first temperature. Specifically, when the first temperature is in the high temperature region (1850 K or higher and lower than 2000 K), the second temperature is set from the low temperature region (1550 K or higher and lower than 1700 K) to the intermediate temperature region (1700 K or higher and lower than 1850 K). In addition, when the first temperature is in the intermediate temperature region (1700 K or higher and lower than 1850 K), the second temperature is set to the low temperature region (1550 K or higher and lower than 1700 K).

Further, the second electric field is set to be higher than the first electric field. Specifically, when the first electric field is in the low electric field region (0.5 GV/m or higher and lower than 1.0 GV/m), the second electric field is set from the intermediate electric field region (1.0 GV/m or higher and lower than 1.5 GV/m) to the high electric field region (1.5 GV/m or higher and lower than 2.0 GV/m). In addition, when the first electric field is in the intermediate electric field region (1.0 GV/m or higher and lower than 1.5 GV/m), the second electric field is set to the high electric field region (1.5 GV/m or higher and lower than 2.0 GV/m).

That is, in the second stage of the operation method according to the invention, the facet is reproduced by setting the temperature of the tip to the second temperature lower than the first temperature, setting the electric field applied to the tip to the second electric field higher than the first electric field, and maintaining the temperature and the electric field for 10 minutes to several hours.

According to the operation method according to the invention, since the facet is reproduced in the second stage after the dark ring is eliminated in the first stage, the emission current can be stabilized in a relatively short time. That is, the point of the invention is to shift the unstable tip in the state of (b) in FIG. 6 to the state of (c) in FIG. 6 and then shift to the state of (a) in FIG. 6.

On the other hand, in the operation method in the related art, the temperature is raised from the operation temperature to the first temperature higher than the second temperature, and the electric field is raised from the operation electric field to the second electric field higher than the first electric field, thereby achieving the reproduction of the facet. According to the operation method in the related art, since both the temperature and the electric field are further raised, the electrostatic force and the surface tension are balanced, the state of (b) in FIG. 6 is maintained, and it takes a long time to reproduce the facet.

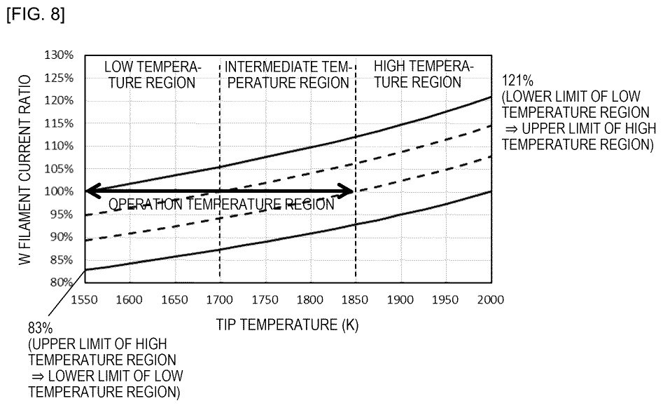

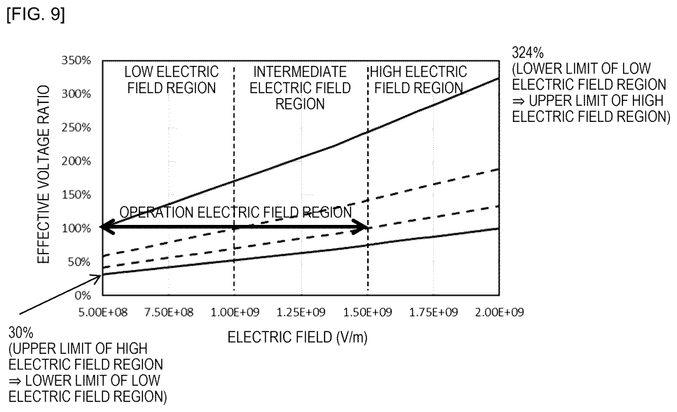

When the operation method according to the invention is executed, the temperature of the tip 4 is set by the current supplied to the filament 3, and the electric field applied to the tip 4 is set by the voltage between the extraction electrode 106 and the suppressor electrode 6. Specifically, the temperature and the electric field of the tip 4 are set based on a relationship between a filament current ratio and the tip temperature shown in FIG. 8 and a relationship between an effective voltage ratio and the electric field shown in FIG. 9.

An example of the relationship between the filament current ratio and the tip temperature will be described with reference to FIG. 8. FIG. 8 is created by measuring the temperature of the tip 4 while changing the filament current supplied to the filament 3 of the Zr/O/W emitter. The horizontal axis represents the tip temperature, and the vertical axis represents the W filament current ratio in which the filament current is normalized. The solid line on the upper side in FIG. 8 indicates a case where the filament current at the tip temperature of 1550 K is 100%, and the solid line on the lower side indicates a case where the filament current at the tip temperature of 2000 K is 100%. In addition, the dotted line on the upper side indicates a case where the filament current at the tip temperature of 1700 K is 100%, and the dotted line on the lower side indicates a case where the filament current at the tip temperature of 1850 K is 100%.

It can be seen from FIG. 8 that when the filament current at the operation temperature is 100%, the filament current at the first temperature higher than the operation temperature may be 101% to 121%. In addition, it can be seen from FIG. 8 that when the filament current at the first temperature is 100%, the filament current at the second temperature lower than the first temperature may be 83% to 99%.

An example of the relationship between the effective voltage ratio and the electric field applied to the tip 4 will be described with reference to FIG. 9. FIG. 9 is created by calculating the electric field applied to the tip 4 according to the effective voltage which is a voltage between the extraction electrode 106 and the suppressor electrode 6 of the Zr/O/W emitter. The horizontal axis represents the electric field, and the vertical axis represents the effective voltage ratio in which the effective voltage is normalized. In FIG. 9, the solid line on the upper side indicates a case where the effective voltage in the electric field of 0.5 GV/m is 100%, and the solid line on the lower side indicates a case where the effective voltage in the electric field of 2.0 GV/m is 100%. The upper dotted line indicates the effective voltage when the electric field is 1.0 GV/m as 100%, and the lower dotted line indicates the effective voltage when the electric field is 1.5 GV/m as 100%.

It can be seen from FIG. 9 that when the effective voltage in the second electric field is 100%, the effective voltage in the first electric field, which is equal to or higher than the operation electric field and lower than the second electric field, may be 30% to 99%. In addition, it can be seen from FIG. 9 that when the effective voltage in the operation electric field is 100%, the effective voltage in the operation electric field and the second electric field higher than the first electric field may be 101% to 324%.

The operation method according to the invention is also effective in preventing the risk of damage due to discharge. Under a high temperature and high electric field, a large amount of electrons emitted from the Schottky emitter collide with the electrode to generate a desorbed gas, and the Schottky emitter may be damaged due to discharge accompanying a decrease in the degree of vacuum. On the other hand, in the operation method according to the invention, by setting one of the temperature and the electric field to be relatively low, the amount of electrons emitted from the Schottky emitter is prevented, and it is possible to reduce the risk of damage due to discharge accompanying a decrease in the degree of vacuum.

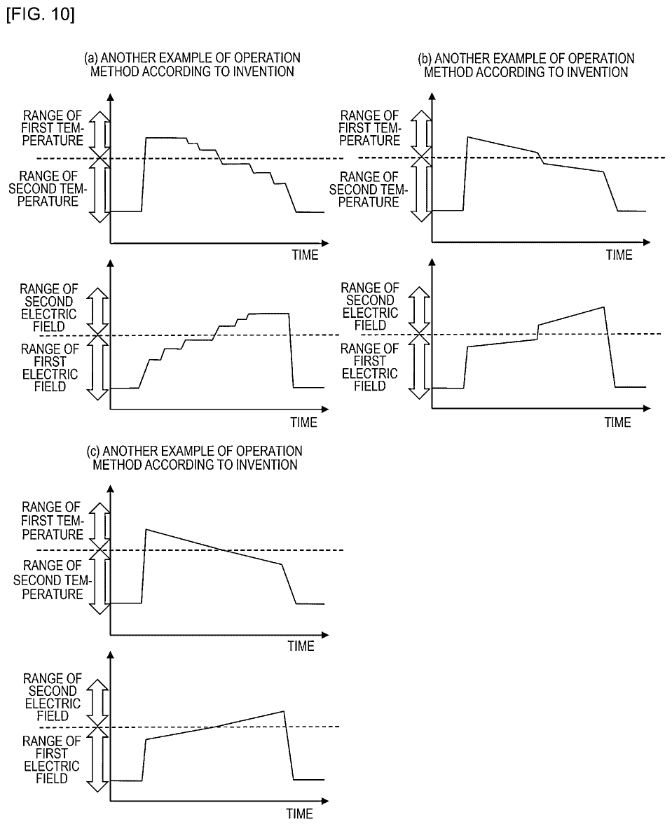

In addition, the invention is not limited to the operation method shown in FIG. 7. Another example of the operation method according to the invention will be described with reference to FIG. 10. In (a) in FIG. 10, the temperature and the electric field are changed in a stepwise manner in the first stage and the second stage. That is, the first temperature, which is a heating temperature in the first stage, is not fixed to a predetermined value, but is lowered in a stepwise manner within a range of the first temperature. In addition, the first electric field, which is an electric field in the first stage, is not fixed to a predetermined value, but is raised in a stepwise manner within a range of the first electric field. Further, the second temperature, which is a heating temperature in the second stage, is lowered in a stepwise manner within a range of the second temperature, and the second electric field, which is an electric field in the second stage, is raised in a stepwise manner within a range of the second electric field. According to the operation method of (a) in FIG. 10, the amount of change in the temperature and the electric field is smaller than that of FIG. 7, so that the shape of the tip end of the tip can be changed more smoothly than the operation method of FIG. 7.

In (b) in FIG. 10, the temperature and the electric field are continuously changed in the first stage and the second stage. That is, the heating temperature in the first stage is continuously lowered within the range of the first temperature. In addition, the first electric field which is the electric field in the first stage is not fixed to the predetermined value, but is continuously raised within the range of the first electric field. In the second stage, the second temperature is also continuously lowered within the range of the second temperature, and the second electric field is also continuously raised within the range of the second electric field. According to the operation method of (b) in FIG. 10, the amount of change in the temperature and the electric field is smaller than that of (a) in FIG. 10, so that the shape of the tip end of the tip can be changed more smoothly than the operation method of (a) in FIG. 10.

In (c) in FIG. 10, the temperature and the electric field are continuously changed from the first stage to the second stage. That is, in the first stage and the second stage, the temperature is continuously lowered, the electric field is continuously raised, and the temperature and the electric field are continuously changed even at a boundary between the first stage and the second stage. According to the operation method of (c) in FIG. 10, the amount of change in the temperature and the electric field is smaller than that of (b) in FIG. 10, so that the shape of the tip end of the tip can be changed more smoothly than the operation method of (b) in FIG. 10.

As shown in FIG. 7, in the operation method of fixing the first temperature, the first electric field, the second temperature, and the second electric field to the predetermined values, the temperature and the electric field can be easily controlled. In addition, in the operation method of (a) in FIG. 10, since the first temperature, the first electric field, the second temperature, and the second electric field are changed in a stepwise manner, the temperature and the electric field are easily controlled as compared with (b) and (c) in FIG. 10. A combination in which the first stage is shown in FIG. 7 and the second stage is any one of (a) to (c) in FIG. 10, or a combination in which the first stage is any one of (a) to (c) in FIG. 10 and the second stage is shown in FIG. 7 may be operated.

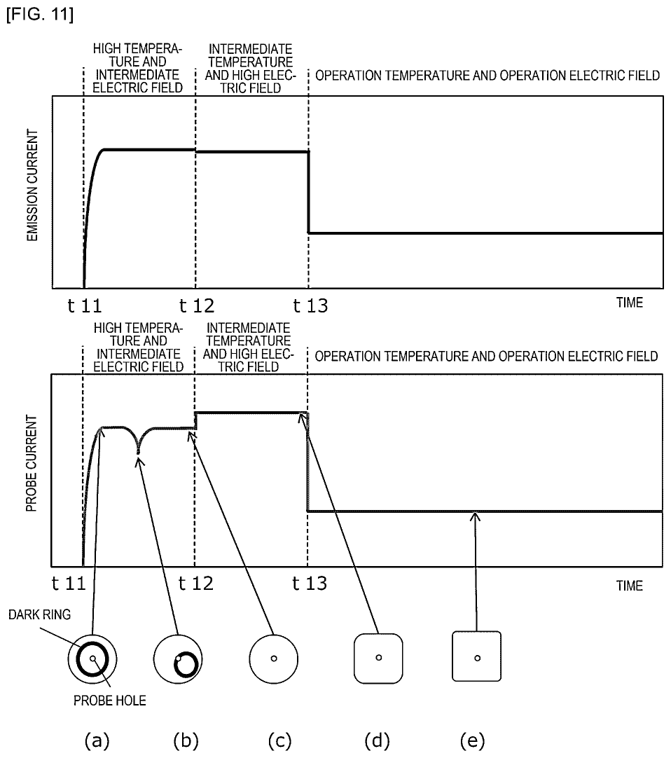

An example, in which the operation method according to the invention is performed on the field emission microscope including the fluorescent surface on which the shape of the electron emission surface is enlarged and projected, will be described with reference to FIG. 11. The upper part of FIG. 11 is a graph showing a temporal change of an emission current, and t11 to t12 is the first stage, t12 to t13 is the second stage, and t13 and thereafter is an operation stage. A current emitted from the Schottky emitter and captured by the fluorescent surface is measured as the emission current. In addition, the lower part of FIG. 11 is a graph showing a temporal change of a probe current, and field emission microscopic images at each time point of (a) to (e) are also shown. A current passing through a probe hole provided at the center of the fluorescent surface is measured as the probe current.

A Zr/O/W emitter is used as the Schottky emitter. In the first stage, the temperature is set to the high temperature region (1850 K or higher and lower than 2000 K), and the electric field is set to the intermediate electric field region (1.0 GV/m or higher and lower than 1.5 GV/m). In the second stage, the temperature is set to the intermediate temperature region (1700 K or higher and lower than 1850 K), and the electric field is set to the high electric field region (1.5 GV/m or higher and lower than 2.0 GV/m). In the operation stage, the operation temperature is set to the low temperature region (1550 K or higher and lower than 1700 K), and the operation electric field is set to the low electric field region (0.5 GV/m or higher and lower than 1.0 GV/m).

In the first stage from t11 to t12, while the emission current increases together with time and then saturates, the probe current once decreases after the initial increase, reaches a minimum value, and then settles at a constant value. During this period, the dark ring confirmed at the time point of (a) moves toward the end portion, and crosses the probe hole at the time point of (b) to minimize the probe current. Thereafter, the probe current becomes a constant value, and the dark ring reaches the end portion and is eliminated. The fact that the field emission microscopic image obtained at the time point of (c) is substantially circular indicates that the tip end of the tip is rounded as shown in (c) of FIG. 6.

In the second stage from t12 to t13, the emission current is equal to that in the first stage, whereas the probe current increases more than that in the first stage as the electric field applied to the tip is raised. Since the emission current remains at a substantially constant value, the risk of damage due to discharge can be reduced. In addition, the fact that the field emission microscopic image, which is substantially circular at the time point of (c), changed to a substantially rectangular shape at the time point of (d) indicates that a facet is formed at the tip end of the tip.

In the operation stage at t13 and thereafter, the temperature and the electric field are lower than those in the second stage, and the emission current and the probe current are lower than those in the second stage. After the dark ring is eliminated in the first stage and the facet is formed in the second stage, the shape of the facet is adjusted as shown in the field emission microscopic image at the time point of (e), and both the emission current and the probe current are stable.

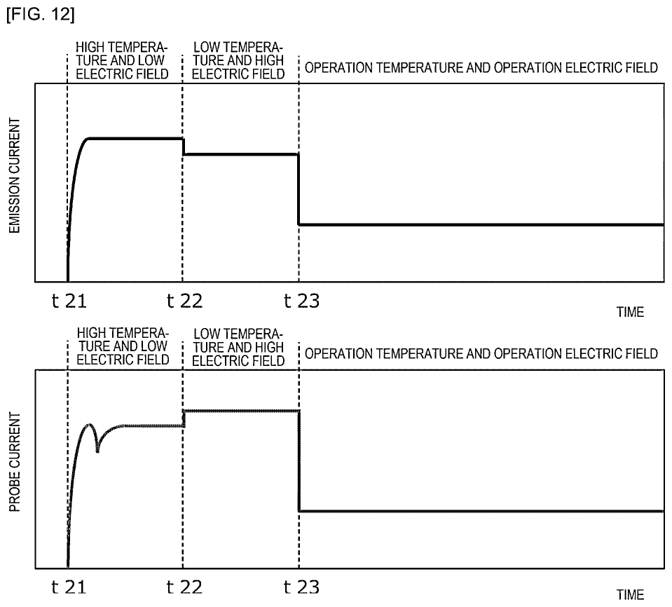

An example in which the operation method according to the invention is performed on the scanning electron microscope will be described with reference to FIG. 12. The upper part of FIG. 12 is a graph showing a temporal change of an emission current, and t21 to t22 is the first stage, t22 to t23 is the second stage, and t23 and thereafter is the operation stage. A current flowing into the Schottky emitter is measured as the emission current. In addition, the lower part of FIG. 12 is a graph showing a temporal change of a probe current. A current reaching the position of the sample is measured as the probe current.

A Zr/O/W emitter is used as the Schottky emitter. In the first stage, the temperature is set to the high temperature region (1850 K or higher and lower than 2000 K), and the electric field is set to the low electric field region (0.5 GV/m or higher and lower than 1.0 GV/m). In the second stage, the temperature is set to the low temperature region (1550 K or higher and lower than 1700 K), and the electric field is set to the high electric field region (1.5 GV/m or higher and lower than 2.0 GV/m). In the operation stage, the operation temperature is set to the low temperature region (1550 K or higher and lower than 1700 K), and the operation electric field is set to the low electric field region (0.5 GV/m or higher and lower than 1.0 GV/m).

In the first stage from t21 to t22, while the emission current increases together with time and then saturates, the probe current once decreases after the initial increase, reaches a minimum value, and then settles at a constant value.

In the second stage from t22 to t23, the emission current decreases more than in the first stage as the temperature is lowered, whereas the probe current increases more than in the first stage as the electric field applied to the tip is raised. Since the emission current remains at a constant value or less, the risk of damage due to discharge can be reduced.

In the operation stage at t23 and thereafter, the temperature and the electric field are lower than those in the second stage, and the emission current and the probe current are lower than those in the second stage. After the dark ring is eliminated in the first stage and the facet is formed in the second stage, both the emission current and the probe current are stable.

The embodiment of the invention has been described above. The invention is not limited to the above embodiment, and can be embodied by modifying components without departing from the gist of the invention. For example, the Schottky emitter is not limited to the Zr/O/W emitter, and may be an emitter using tantalum (Ta), a boron single crystal such as LaB₆ or CeB₆, a carbide single crystal such as ZrC, HfC, or TiC, or a nitride single crystal such as ZrN or TiN as the tip instead of the W single crystal. In addition, an emitter using HfO₂ or the like as the reservoir instead of ZrO₂ may be used. However, it is preferable that the temperatures and the electric fields in the first stage and the second stage are appropriately set according to materials of the tip and the reservoir.

A plurality of components disclosed in the above embodiment may be combined appropriately. Further, some components may be deleted from all the components shown in the above embodiment.

### REFERENCE SIGNS LIST

1: insulator
2: electrode pin
3: filament
4: tip
5: reservoir
6: suppressor electrode
7: columnar crystal structure
8: facet
9: dark ring
100: emitter
101: computer
102: controller
103: acceleration power supply
104: heating power supply
105: extraction power supply
106: extraction electrode
107: suppressor power supply
109: electron beam
110: anode
111: first condenser lens
112: aperture
113: second condenser lens
114: astigmatism correction coil
115: objective lens
116: deflection scanning coil
117: sample
118: secondary electron detector
1000: scanning electron microscope

1. An electron beam device including a Schottky emitter comprising:
a heating source configured to heat the Schottky emitter;
a power supply configured to apply an electric field to the Schottky emitter; and
a control unit configured to control the heating source and the power supply, wherein
the control unit is configured to execute a first stage of applying a first electric field to the Schottky emitter while heating the Schottky emitter at a first temperature, and a second stage of applying a second electric field to the Schottky emitter while heating the Schottky emitter at a second temperature,
the first temperature is higher than an operation temperature of the Schottky emitter and the second temperature,
the first electric field is equal to or higher than an operation electric field of the Schottky emitter and lower than the second electric field,
the second temperature is equal to or higher than the operation temperature and lower than the first temperature, and
the second electric field is higher than the operation electric field and the first electric field.

2. The electron beam device according to claim 1, wherein,
when the Schottky emitter is a Zr/O/W emitter including a tip of a tungsten single crystal and a reservoir of zirconium oxide,
the first temperature is 1700 K or higher and lower than 2000 K when the operation temperature is 1550 K or higher and lower than 1700 K, the first temperature is 1700 K or higher and lower than 2000 K when the operation temperature is 1700 K or higher and lower than 1850 K, and
the second temperature is 1550 K or higher and lower than 1700 K when the first temperature is 1700 K or higher and lower than 1850 K, and the second temperature is 1550 K or higher and lower than 1850 K when the first temperature is 1850 K or higher and lower than 2000 K.

3. The electron beam device according to claim 1, wherein,
when the Schottky emitter is a Zr/O/W emitter including a tip of a tungsten single crystal and a reservoir of zirconium oxide,
the first electric field is 0.5 GV/m or higher and lower than 1.5 GV/m, and
the second electric field is 1.0 GV/m or higher and lower than 2.0 GV/m when the operation electric field is 0.5 GV/m or higher and lower than 1.0 GV/m, and the second electric field is 1.5 GV/m or higher and lower than 2.0 GV/m when the operation electric field is 1.0 GV/m or higher and lower than 1.5 GV/m.

4. The electron beam device according to claim 1, wherein
the Schottky emitter is a Zr/O/W emitter including a tip of a tungsten single crystal and a reservoir of zirconium oxide, and when the heating source supplies a filament current to the Zr/O/W emitter,
the control unit sets the filament current at the first temperature to 101% to 121% when the filament current at the operation temperature is 100%, and sets the filament current at the second temperature to 89% to 99% when the filament current at the first temperature is 100%.

5. The electron beam device according to claim 1, wherein
the Schottky emitter is a Zr/O/W emitter including a tip of a tungsten single crystal and a reservoir of zirconium oxide, and when the power supply applies an effective voltage to the Zr/O/W emitter,
the control unit sets the effective voltage in the first electric field to 30% to 99% when the effective voltage in the second electric field is 100%, and sets the effective voltage in the second electric field to 101% to 324% when the effective voltage in the operation electric field is 100%.

6. The electron beam device according to claim 1, wherein
the control unit is configured to fix the first temperature, the first electric field, the second temperature, and the second electric field to predetermined values.

7. The electron beam device according to claim 1, wherein
the control unit is configured to change the first temperature, the first electric field, the second temperature, and the second electric field in a stepwise manner.

8. The electron beam device according to claim 1, wherein
the control unit is configured to continuously change the first temperature, the first electric field, the second temperature, and the second electric field.

9. A method of operating a Schottky emitter, the method comprising:
executing a first stage of applying a first electric field to the Schottky emitter while heating the Schottky emitter at a first temperature, and a second stage of applying a second electric field to the Schottky emitter while heating the Schottky emitter at a second temperature, wherein
the first temperature is higher than an operation temperature of the Schottky emitter and the second temperature,
the first electric field is equal to or higher than an operation electric field of the Schottky emitter and lower than the second electric field,
the second temperature is equal to or higher than the operation temperature and lower than the first temperature, and
the second electric field is higher than the operation electric field and the first electric field.
